(19) United States
(12) Patent Application Publication
(10) Pub. No.: US 2009/0072333 A1
(43) Pub. Date: Mar. 19, 2009

(54) SENSOR ARRAY HAVING A SUBSTRATE AND A HOUSING, AND METHOD FOR MANUFACTURING A SENSOR ARRAY

(76) Inventors: Frieder Haag, Wannweil (DE); Thomas-Achim Boes, Wennweil (DE)

Correspondence Address: KENYON & KENYON LLP, ONE BROADWAY, NEW YORK, NY, 10004, US

(21) Appl. No.: 12/063,785

(22) PCT Filed: Jul. 7, 2006
(86) PCT No.: PCT/EP06/63999

§ 371 Date: Nov. 18, 2008

(30) Foreign Application Priority Data
Aug. 16, 2005 (DE) 10 2005 038 443.9

(51) Int. Cl. H01L 29/84; H01L 21/50

(52) U.S. Cl. 257/415; 438/51; 257/E21.499; 257/E29.324

(57) ABSTRACT

In a sensor array having a substrate and a housing, and in a method for manufacturing a sensor array are proposed, the housing substantially completely surrounds the substrate in a first substrate area, the housing is provided in a second substrate area at least partly open via an opening, and the second substrate area is provided protruding from the housing in the area of the opening.

### BACKGROUND INFORMATION

The present invention is directed to a sensor array having a substrate and a housing according to the definition of the species in the main claim. German Unexamined Application DE 199 29 026 A1 describes a method for manufacturing a pressure sensor in which a semiconductor pressure sensor is applied to an assembly section of a lead frame, the semiconductor pressure sensor is electrically connected to contact sections of the lead frame, the lead frame containing the semiconductor pressure sensor is set into an injection molding die and subsequently the semiconductor pressure sensor in the injection molding die is encapsulated by an injection molding compound, means being provided in the injection molding die whereby a pressure supply duct for the semiconductor pressure sensor is carved out of the sheathing and the injection molding compound, a male die being situated in the injection molding die spaced by a gap from the side of the assembly section facing away from the semiconductor pressure sensor. As an alternative, it is known to pack sensors requiring access to external media, such as pressure sensors, in premolded housings. For this purpose, the housing mold is initially injected and subsequently the chip is mounted in the already pre-manufactured housing and contacted as appropriate. Because the so-called premold housing molds are relatively expensive compared to standard mold housings, it has been attempted via the above-cited Unexamined Application, to pack also pressure sensors in standard mold housings. For this purpose, part of the component surface area is kept free using a male die or the like, for example. The disadvantage of all existing housing molds is that the sensor element is at least partially embedded in a plastic compound. The characteristics curve of the sensor element may be considerably affected by thermal expansion. This is possible, for example, due to the fact that different thermal expansion coefficients result in stresses in the sensor element, which cause erroneous measurements or function failures.

### SUMMARY OF THE INVENTION

The sensor array according to the present invention having a substrate and a housing, and the method according to the present invention for manufacturing a sensor array having the features of the other independent claims, have the advantage over the related art that the active sensor area of the sensor array may be considerably better protected against stress effects induced by the housing. For this purpose, the substrate has a first substrate area and a second substrate area, an active sensor area such as a pressure sensor diaphragm or the like being located in the second substrate area and the second substrate area being provided so that it protrudes from the housing. In the junction area between the first and second substrate area, the housing has an opening in the second substrate area. Due to the fact that the second substrate area is provided protruding from the housing, the housing is designed in such a way that the sensor, i.e., the substrate having the active sensor area, is embedded in the molding compound, i.e., the housing material, only on one side, namely in the area of its first substrate area. This may be achieved according to the present invention, for example, by designing the sensor in the shape of a bar. Therefore, the substrate having the sensor element, i.e., the active area located in the second substrate area, is advantageously provided embedded in the housing only in the first substrate area. It is further advantageous that the first substrate area and the second substrate area are provided monolithically connected or surrounded thereby. This means that the first and second substrate areas are preferably a continuous substrate material, the partition between first substrate area and second substrate area arising by the fact that parts of the substrate are embedded in the housing (first substrate area) and parts thereof protrude from the housing (second substrate area). Of course, the substrate may also be a composite substrate material, for example, a semiconductor substrate having a cap wafer or also a composite or bonded or also a grown-on substrate such as an SOI or the like. It is further preferable that an injection molding compound is provided as the housing. For this purpose, proven manufacturing methods for providing housings for semiconductor components or, in general, for electronic components, may be used, in particular the so-called transfer molding method, in which a housing is manufactured from a molding compound by embedding the component, i.e., a semiconductor sensor array, into the housing.

It is further preferable that the housing surrounds the second substrate area at least partially on a main level of the substrate at a distance. This makes it advantageously possible according to the present invention that the second substrate area protruding from the housing is protected against mechanical stresses which could be caused by the housing, while it is also protected by the housing itself which, however, is situated at a distance from the substrate in the area of the second substrate area, in particular against external forces such as being dropped or the like. It is furthermore preferable according to the present invention that the second substrate area has an active area for sensing a detectable quantity or a plurality of detectable quantities, the quantity or quantities being detectable only with the aid of an at least indirect contact of at least one part of the sensor array with a medium. This makes it advantageously possible according to the present invention, on the one hand, that the active sensor area is accessible for a medium, for example, a fluid under pressure and whose pressure is to be measured, and, on the other hand, that an even more cost-effective, simple, and rapid manufacture of the entire sensor array, i.e., including a housing for the substrate having the active area, is possible according to the present invention. As an alternative thereto, i.e., that a medium contact exists between an active sensor area and a medium, it is also possible, of course, to use the sensor array according to the present invention for sensor principles in which no media contact is present or required, for example, inertial sensors. In such sensor principles requiring no media contact, it is also advantageous in particular that introduction of stress from the housing to the active sensor area is largely avoided. It is furthermore preferable according to the present invention that the first substrate area has contact means for electrical contacting and/or switching means and that only relatively insensitive structures are provided in the substrate at the junction between the first substrate area and the second substrate area. Such relatively insensitive structures include, for example, printed conductors, which provide contact lines from the circuit part in the first substrate area to the active area in the second substrate area. It is thus possible according to the present invention to provide a functionally adequate junction from the first substrate area to the second substrate area without loss of yield or the like and without additional costs only via a rational arrangement of the different functional areas on the substrate according to the present invention of the semiconductor array, i.e., the sensor array, i.e., in particular via an effective seal between an injection mold and the substrate of the sensor array when the first substrate area is coated with the casting compound. It is furthermore preferable that a sealing material, in particular a gel or a foil, is provided at the junction between the first substrate area and the second substrate area. This makes it advantageously possible to achieve, on the one hand, a better seal between the injection molding die and the substrate and, on the other hand, better protection for the substrate structures located between the first substrate area and the second substrate area. In addition, this results in even sensitive structures being locatable in this junction zone, so that the required overall chip surface for manufacturing the substrate of the sensor array may be reduced.

Another subject matter of the present invention is a method for manufacturing a sensor array according to the present invention, in which in particular the housing is manufactured by coating the substrate and the substrate is essentially fully surrounded by the housing only in its first substrate area. In contrast, the remaining substrate area (second substrate area), protrudes from the housing. It is preferable in this case that, when coating for sealing an injection molding die between the first substrate area and the second substrate area, part of the injection molding die either has direct contact with the substrate or, when coating for sealing an injection molding die between the first substrate area and the second substrate area, part of the injection molding die presses onto a sealing material. The sealing material may be either built into the sensor array during the manufacture of the housing, for example, by applying the sealing material onto the substrate (between the first and second substrate areas) and subsequently casting the housing material, i.e., subsequently at least partially also embedding the sealing material into the housing (consumption of the sealing material in manufacturing the housing). Alternatively, the sealing material may also be provided part of an injection molding die or, at least, applied thereto for sealing (for example, as a sealing foil or as a soft sealing compound). In this case, the sealing material is at least not to a major degree embedded into the housing.

### BRIEF DESCRIPTION OF THE DRAWINGS

Exemplary embodiments of the present invention are illustrated in the drawings and explained in greater detail in the description that follows.

FIG. 1 shows a schematic top view onto a sensor array according to the present invention,

FIG. 2 shows a schematic representation of a sectional view through a sensor array according to the present invention based on section line AA of FIG. 1,

FIG. 3 shows a schematic top view onto a sensor array according to the present invention with further details of the inside of the sensor array,

FIG. 4 shows a schematic top view of a second specific embodiment of a sensor array according to the present invention,

FIG. 5 shows a schematic sectional view of the second specific embodiment of the sensor array according to the present invention on the basis of section line AA of FIG. 4, and

FIG. 6 shows a schematic sectional view of a third specific embodiment of a sensor array according to the present invention.

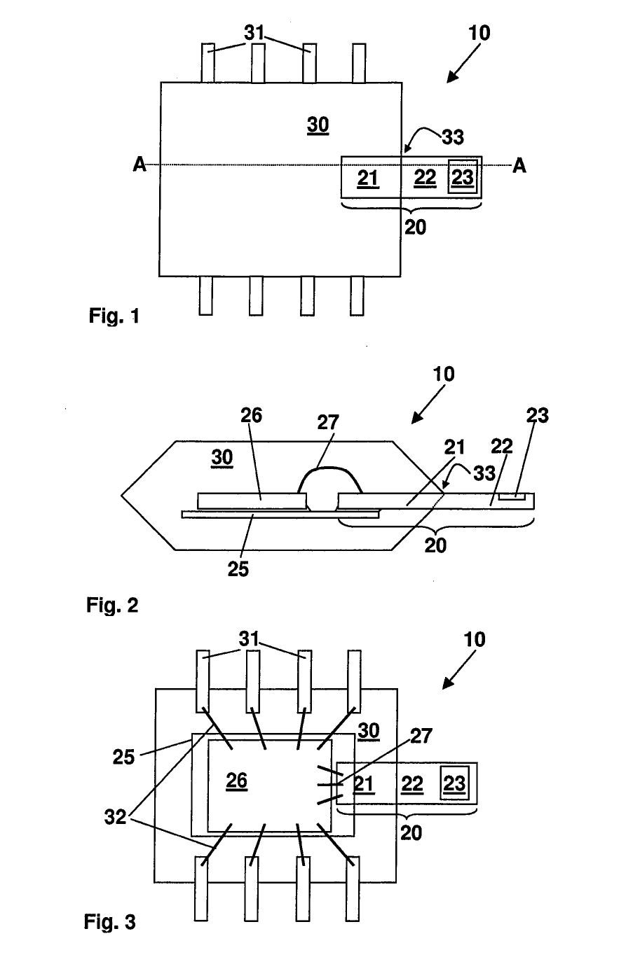

FIG. 1 shows a schematic top view onto a sensor array 10 according to the present invention. This sensor array 10 includes a housing 30 and a substrate 20. The substrate material is provided in particular as a semiconductor material or as a composite substrate, for example, of wafers of different or identical materials. In the following, the substrate material is referred to as substrate 20. Substrate 20 has a first area 21 and a second area 22, an active area 23 which is used for sensing or detecting a quantity which is to be measured with the aid of sensor array 10 according to the present invention being shown separately in second area 22. There is an opening 33 in housing 30 in second substrate area 22 in the junction area to first substrate area 21, so that second substrate area 22 may protrude to the outside. The quantity to be detected with the aid of active area 23 is, in particular, a quantity which is detectable only with the aid of an at least indirect contact between second substrate area 22, in particular active area 23, and a medium not illustrated in the figures. The medium may be a gas, for example, whose pressure is to be measured with the aid of a pressure measuring diaphragm as active area 23. The medium, such as air or another gas, must have access to area 23, i.e., in particular to the pressure measuring diaphragm. This access to active area 23 is implemented according to the present invention in that second substrate area 22 protrudes from housing 30 and first substrate area 21 is embedded in housing 30. FIG. 1 shows a section line AA, FIG. 2 being a schematic representation of sensor array 10 according to the present invention according to section line AA of FIG. 1, except for certain differences. In FIG. 1 it is also apparent that connecting elements 31 in particular, such as pins or the like, protrude from housing 30. It is, however, also possible according to the present invention that no contacting elements 31 protrude from housing 30, but there are contact surfaces (not illustrated) on the top, the bottom, and/or the lateral surfaces of housing 30, which are used for contacting the component, i.e., the sensor array, for example, via a flip chip assembly option or the like.

FIG. 2 shows sensor array 10 according to the present invention, including first substrate area 21, second substrate area 22, active area 23, housing 30, and opening 33. In addition, a special exemplary specific embodiment is indicated in FIG. 2, in which, in addition to substrate 20, another substrate 26 is present, which, for example, includes further circuit elements for evaluating the signals of active area 23. For this purpose, substrate 20 and further substrate 26 are connected with the aid of a connecting line 27, in particular in the form of a bond wire 27. In the example of the system of FIG. 2, both substrate 20 and further substrate 26 are situated on a so-called lead frame 25, i.e., glued or otherwise fastened onto lead frame 25.

FIG. 3 shows another schematic top view onto the sensor array according to the present invention, FIG. 3 showing further details of the inside of sensor array 10 such as, in addition to substrate 20, first substrate area 21, second substrate area 22, active area 23, further substrate 26, and bond wires 27, further bond wires 32 for contacting further substrate 26 with connecting elements 31 . . . . In addition, FIG. 3 shows lead frame 25.

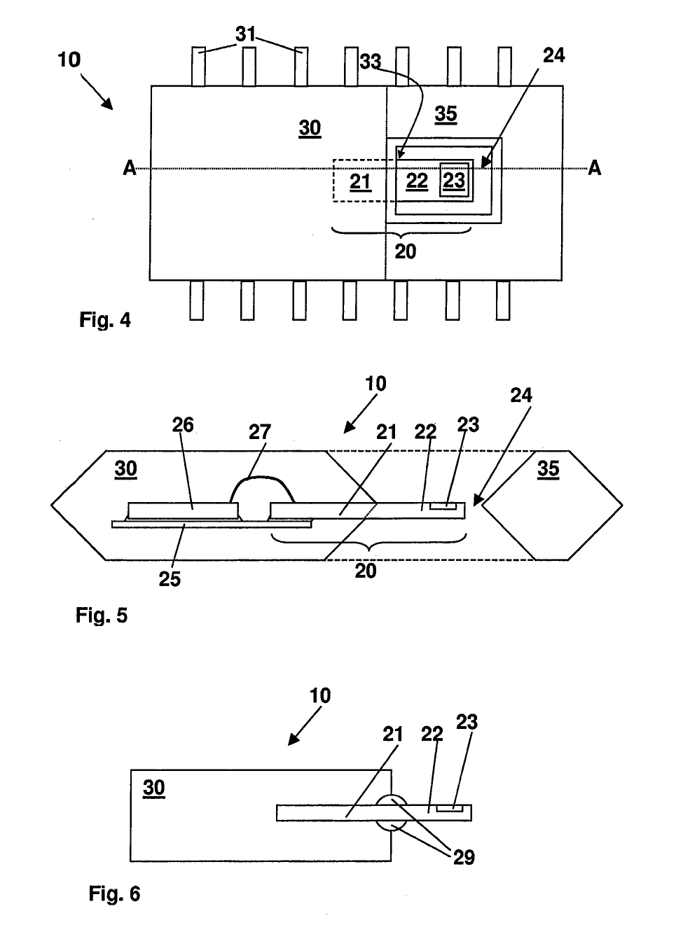

FIG. 4 shows a second specific embodiment of sensor array 10 according to the present invention in a schematic top view. Again, substrate 20 has first substrate area 21 and second substrate area 22, second substrate area 22, on the one hand, including active area 23 and, on the other hand, protruding from housing 30 at opening 33. Unlike the first exemplary embodiment, however, housing 30 has an extension area 35, which extends essentially in the main plane of substrate 20 around second substrate area 22 and thus protects second substrate area 22 against mechanical influences in particular. However, here the advantages of the present sensor array according to the present invention are implemented to the extent that, although additional area 35, i.e., extension area 35 of the housing protects second substrate area 22, it exerts no mechanical forces, for example, due to different temperature coefficients or the like, on second substrate area 22 and, in particular on active area 23 of the sensor array because extension area 35 keeps a distance from second substrate area 22, this distance being indicated by reference numeral 24 in FIG. 4. FIG. 4 furthermore shows a section line AA, FIG. 5 essentially representing a sectional representation (with certain differences) along section line AA of FIG. 4.

FIG. 5 shows the above-mentioned schematic sectional representation along section line AA (with differences) of FIG. 4, sensor array 10 according to the present invention again including substrate 20, first substrate area 21, second substrate area 22, active area 23, further substrate 26, extension area 35, and leadframe 25.

FIG. 6 schematically shows a third specific embodiment of the sensor array according to the present invention, substrate 20 again including first substrate area 21, second substrate area 22, and active area 23; however, in the junction area between first substrate area 21 and second substrate area 22, i.e., in the area of opening 33, a sealing material 29 is provided, which is used in the manufacture of housing 30 of sensor array 10 to the extent that an injection molding die (not illustrated) or an extrusion molding die of a device for coating first substrate area 21 with the housing material should not have a direct contact or exert any direct pressure force on substrate 20 in the junction area between first substrate area 21 and second substrate area 22, but should press on sealing material 29 and thus protect the structures located in this substrate area against these pressure forces to be used. The material of housing 30 may thus be filled in the area to be coated (first substrate area 21) using the required pressure and the required temperature, which, in addition, does not affect the speed of the manufacturing process of sensor array 10 according to the present invention. One of the main problems in coating only one partial area 21 of substrate 20 is that sealing of the tool against the molding compound or against the casting compound of housing 30 may cause problems. Due to tolerances, excessive pressure must be used when sealing, because otherwise excess plastic (flash) flows into active area 23 of the sensor, i.e., of substrate 20, causing interfering casting compound deposits. To eliminate this problem, it is provided according to the present invention that either no active structures or only track conductors be located in the junction area between the first and second substrate areas, i.e., in the area of the required sealing by the injection mold, but that sealing by pressing the tool directly onto the silicon be avoided and the seal be implemented using soft compounds such as gels or foils. As another option according to the present invention, it is also provided not to provide any active or sensitive structures in the area of a needed seal and additionally to provide a seal using soft compounds (sealing material 29). According to the present invention, sealing material 29 may be either embedded in housing 30 as FIG. 6 shows (i.e., remain on finished sensor array 10) or, in a specific embodiment of the method according to the present invention which is not illustrated, be provided only on the injection molding die, so that the injection molding die does not “press” onto substrate 20 with a “hard” material for sealing, but with a soft material such as a film or a gel. In the latter case, sealing material 29 is not (or not to a considerable degree) embedded in housing 30.

The silicon side is more difficult to seal because an angular rotation may contribute to forming a gap. It is advantageous here that the active surface of the sensor is situated on the top of the bar, i.e., of substrate 20 protruding in substrate area 22, and thus a slight flash formation (i.e., on the lateral narrow sides of substrate 20) is not critical for the function of the sensor. The third specific embodiment of sensor array 10 according to the present invention may, of course, be combined with the first and/or the second specific embodiment.

It is also possible according to the present invention that the sensor is isolated from the electronic analyzer circuit, i.e., that a so-called two-chip module is provided within sensor array 10 as illustrated in FIGS. 2, 3, and 5, or that the sensor, i.e., substrate 20 already includes the electronic analyzer circuit and therefore no additional substrate 26 is required, so that sensor array 10 may be implemented as a single-chip module.

The first specific embodiment of sensor array 10 according to the present invention (FIGS. 1, 2, and 3) is particularly advantageous if the smallest possible dimension of the sensor array is desirable or the sensor element, e.g., for biosensors or the like, is to be immersed in a fluid which should not contact the molding compound, i.e., the casting compound of housing 30. The shape of the housing of sensor array 10 according to the second specific embodiment (FIGS. 4 and 5) in which extension area 35 of housing 30 surrounds second substrate area 22 and protects active area 23, offers maximum protection against mechanical influences on sensor element 23, i.e., active area 23 of sensor array 10. According to the present invention, second substrate area 22 is in contact with housing 30 only on one of its sides (and not at all in extension area 35). According to the present invention, housing 30 may be a housing mold having pins, but also a modern “leadless” mold.

1-10. (canceled)

11. A sensor array, comprising:
a substrate; and
a housing substantially completely surrounding the substrate in a first substrate area, the housing being provided in a second substrate area at least partly open via an opening;
wherein the second substrate area protrudes from the housing in an area of the opening.

12. The sensor array according to claim 1, wherein the substrate is embedded in the housing only in the first substrate area.

13. The sensor array according to claim 1, wherein the first substrate area and the second substrate area are monolithically connected.

14. The sensor array according to claim 1, wherein an injection molding compound is provided as the housing.

15. The sensor array according to claim 1, wherein the housing surrounds the second substrate area at least partially on a main plane of the substrate at a distance.

16. The sensor array according to claim 1, wherein the second substrate area has an active area configured to sense at least one quantity detectable only via an at least indirect contact of at least one part of the sensor array with a medium.

17. The sensor array according to claim 1, wherein the first substrate area has at least one of (a) a contact device configured for electrical contact and (b) a switching device and only relatively insensitive structures are provided in the substrate at a junction between the first substrate area and the second substrate area.

18. The sensor array according to claim 1, wherein at least one of (a) a sealing material, (b) a gel, and (c) a foil is provided at a junction between the first substrate area and the second substrate area.

19. A method for manufacturing a sensor array including a substrate and a housing substantially completely surrounding the substrate in a first substrate area, the housing being provided in a second substrate area at least partly open via an opening, the second substrate area protruding from the housing in the area of the opening, comprising:
manufacturing the housing by coating the substrate so that the substrate is substantially completely surrounded by the housing only in the first substrate area.

20. The method according to claim 19, wherein at least one of (a) when coating for sealing an injection molding die between the first substrate area and the second substrate area, part of the injection molding die has direct contact with the substrate and (b) when coating for sealing an injection molding die between the first substrate area and the second substrate area, part of the injection molding die presses onto a sealing material.
